(19) United States
(12) Patent Application Publication
(10) Pub. No.: US 2017/0324217 A1
(43) Pub. Date: Nov. 9, 2017

(54) METHOD FOR PRODUCING A RESONANT STRUCTURE OF A DISTRIBUTED-FEEDBACK SEMICONDUCTOR LASER

(71) Applicant: THALES, COURBEVOIE (FR)

(72) Inventors: Mathieu CARRAS, GENTILLY (FR); Grégory MAISONS, LE CHESNAY (FR); Bouzid SIMOZRAG, VIRY CHATILLON (FR)

(21) Appl. No.: 15/513,376

(22) PCT Filed: Sep. 25, 2015
(86) PCT No.: PCT/EP2015/072099

§ 371 Date: Mar. 22, 2017

(30) Foreign Application Priority Data
Sep. 26, 2014 (FR) 1402166

(51) Int. Cl. H01S 5/12; H01S 5/20; H01S 5/042; H01S 5/026; G02B 6/122; H01S 5/227; G02B 5/18

(52) U.S. Cl. CPC H01S 5/1231; H01S 5/2275; H01S 5/2086; G02B 5/1866; H01S 5/026; G02B 6/122; H01S 5/0425

(57) ABSTRACT

A reproducible method for producing a resonant structure of a distributed-feedback semiconductor laser exhibiting a narrow waveguide of the order of some ten micrometers, the production of the diffraction grating being carried out subsequent to the step of producing the strip is provided. In a last step, a diffraction grating is engraved as a function of a desired precise wavelength.

The invention lies in the field of quantum cascade lasers, and, more particularly, of distributed-feedback semiconductor lasers.

More precisely, the invention relates to a method for producing a resonant structure of a distributed-feedback semiconductor laser according to a technology of metallized surface gratings.

By quantum cascade laser, or QCL, is meant a semiconductor laser able to emit a photon in a domain of wavelengths ranging from the mid-infrared to the far infrared, the laser emission being obtained by inter-sub-band transitions of a quantum confinement structure.

By distributed-feedback, or DFB, semiconductor laser is meant a semiconductor laser implementing an optical guide and possessing a grating allowing distributed feedback, the grating being able to be of surface metallic type.

The technology of distributed-feedback semiconductor lasers possessing a surface metallic grating makes it possible in particular to achieve gain coupling. This entails growing all the constituent layers of the resonant structure and thereafter etching a diffraction grating in the upper guide and then metallizing.

A procedure for producing a resonant structure of a distributed-feedback semiconductor laser according to the technology of metallized surface gratings according to the prior art consists in constructing the grating on the upper surface of a stack of layers comprising semi-conducting materials and thereafter constructing cavities making it possible to define a strip.

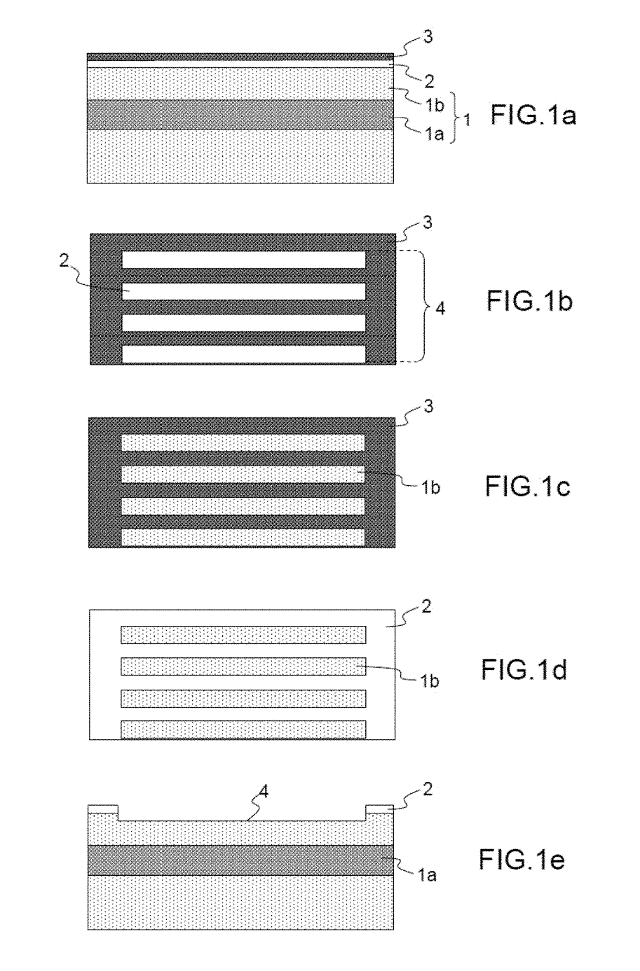

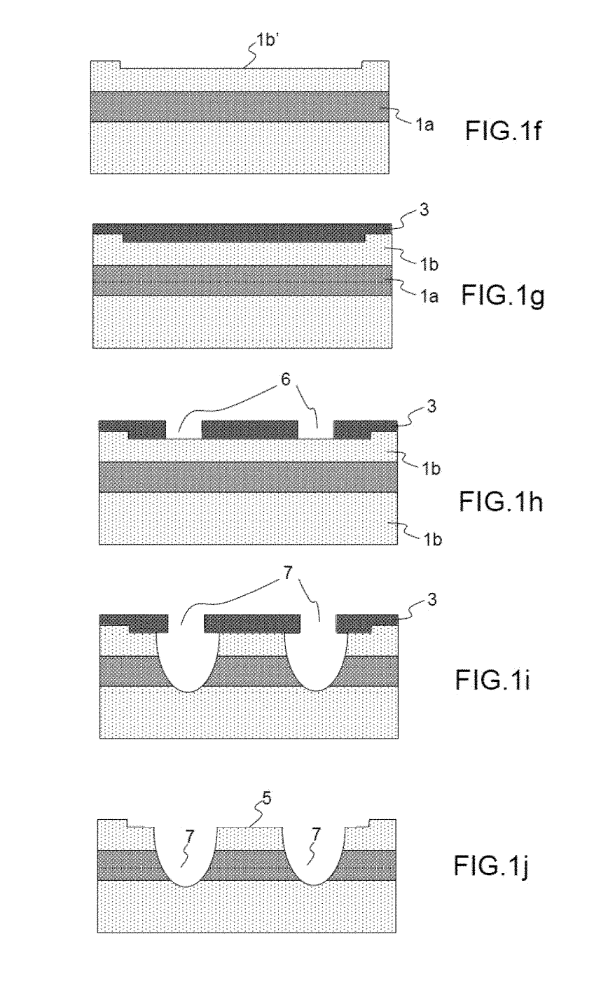

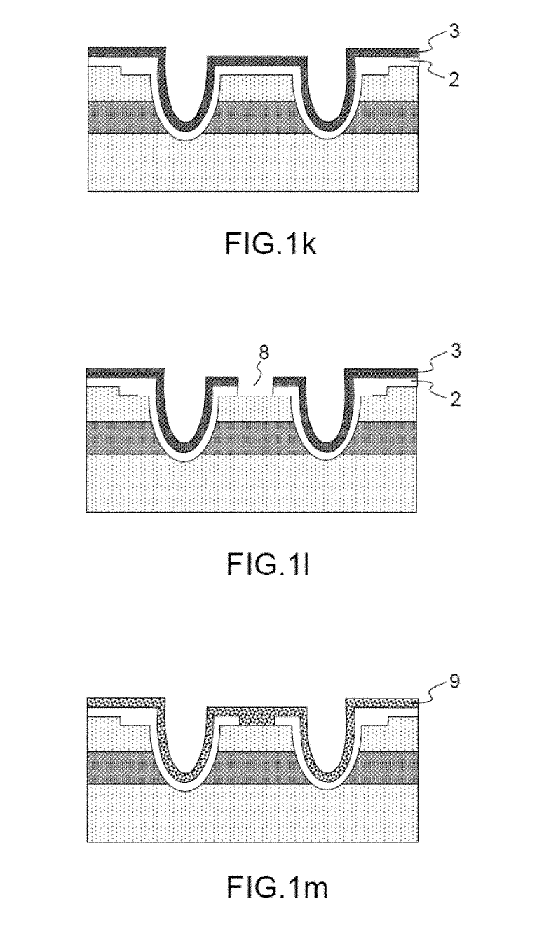

The steps of constructing a resonant structure of a distributed-feedback semiconductor laser according to the technology of metallized surface gratings according to the prior art are detailed in FIGS. 1a to 1m.

In a first step, the upper surface of a multilayer stack 1 comprising semi-conducting materials 1a; 1b is entirely covered with a layer comprising an electrical insulating material 2 and then coated with a provisional layer 3.

The electrical insulating layer 2 serves as hard mask for the dry etching of the gratings.

In this instance, the provisional layer 3 comprises PMMA, the acronym standing for poly(methylmethacrylate).

The pattern of the diffraction grating 4 is thereafter engraved in the provisional layer 3 by applying an electron beam, the electron beam reproducing the pattern of the grating 4 desired on the provisional layer 3.

FIG. 1a represents a profile view of the stack 1 after the first step.

The second step of development consists of the immersion of the surface covered with PMMA in a solvent so as to remove all the surface zones covered with PMMA which were subjected to the electron beam.

FIG. 1b represents a view from above of the upper surface of the stack 1 after the second development step. The surface of the stack 1 comprises a first zone comprising the provisional material 3 and second zones on which the provisional material 3 has been removed exposing the layer of dielectric material 2, the second zones without the provisional material 3 reproducing the pattern of the diffraction grating 4.

FIG. 1c represents a view from above of the upper surface of the stack 1 after the third step of etching the dielectric material 2. In this instance, the etching procedure is a reactive ion etching, or RIE, the plasma used comprising CHF₃. This step of etching the dielectric material 2 makes it possible to re-expose the semi-conducting material 1b situated on the surface of the stack 1. The parts comprising the semi-conducting material 1b reproducing the pattern of the diffraction grating 4.

The fourth step corresponds to the removal of the provisional material 3 that has not yet been removed. The surface of the stack 1 is therefore immersed in a solvent comprising acetone.

The surface of the stack 1 exposes the pattern of the grating 4: the semi-conducting material 1b exhibiting the pattern of the grating 4 and the dielectric material 2 exhibiting the negative of the pattern of the diffraction grating 4, as indicated in FIG. 1d.

In a fifth step, the grating 4 is etched in the semi-conducting material 1b.

FIG. 1e represents a profile view of the stack 1, the surface of the stack 1 being etched.

The sixth step consists in the removal of the dielectric material 2. In this instance the removal is carried out by immersing the surface of the stack 1 in a bath comprising hydrofluoric acid.

FIG. 1f represents the profile of the stack 1, the surface of the stack 1 being etched and the dielectric material 2 removed.

The seventh step consists of the coating of the surface of the stack 1 with a layer comprising a provisional material 3.

FIG. 1g represents the profile of the stack 1 whose surface is covered with a layer of provisional material 3.

An eighth step consists in the removal of the provisional material 3 by optical lithography on at least two zones 6 revealing the semiconductor 1b of the stack 1.

FIG. 1h presents the stack 1 after opening of the provisional material 3.

In a ninth step, the stack 1 is chemically etched at the level of the two zones 6 of openings of the provisional material 3 so as to form at least two cavities 7. The chemical etching procedure makes it possible furthermore to prevent the pattern of the grating 4 from being engraved on the flanks of the strip 5.

FIG. 1i presents a profile view of the stack 1 after chemical etching of the cavities 7. The cavities 7 extend beyond the two opening zones 6. Indeed, the cavities 7 extend in part below the mask consisting of the provisional material 3. The strip 5 is ultimately narrower than the mask formed by the layer of provisional material 3, the difference between the mask and the strip 5 being difficult for the operator to control.

In a tenth step, the provisional material 3 that served as mask during the ninth step of chemical etching is removed by immersing the surface of the stack 1 in a solvent comprising acetone.

FIG. 1j presents a profile view of the stack 1, the surface of the stack 1 exhibiting two cavities 7 and a strip 5 situated between the two cavities 7 and on which the diffraction grating 4 is etched.

In an eleventh step, the surface of the stack 1 is entirely covered with a layer of dielectric material 2 and then coated with a layer of provisional material 3, as represented in FIG. 1k.

The electrical insulating layer 2 makes it possible to insulate the semiconductor stack 1 from the remainder of the resonant structure, the electrical insulating material 2 being able to be a deposition of silicon nitride or of silica.

In a twelfth step, a part of the provisional material 3 and of the dielectric material 2 is removed by optical lithography and RIE etching to form an opening 8.

FIG. 1l represents a profile view of the stack 1 after the formation of the opening 8 of the dielectric layer 2 and of provisional material 3. Stated otherwise, the layer of dielectric material 2 and the layer of provisional material 3 cover in part the diffraction grating 4 etched on the strip 5, or, stated otherwise, the diffraction grating 4 is partially covered by the layer of silica 2 and of provisional material 3.

In a thirteenth step, FIG. 1m, the provisional material 3 is removed and the surface of the stack 1 is covered with a metallic layer 9 comprising in particular gold.

A drawback of this procedure is the lack of reproducibility during formation of the strip 5 by chemical etching.

Chemical etching is a procedure allowing only low precision. FIG. 1i does indeed evidence the difficulties posed by the chemical etching procedure when constructing the strip 5. Indeed the semi-conducting material stack 1a; 1b is etched beyond the two zones 6 predefined by the provisional material mask 3, and is so with little control on the part of the operator.

This drawback is all the more annoying when one wishes to construct narrow waveguides. Indeed, the risk is of completely etching the strip 5 exhibiting the diffraction grating 4 and of not being able to obtain a waveguide.

An aim of the invention is to propose a reproducible method for producing a resonant structure of a distributed-feedback semiconductor laser exhibiting a narrow waveguide of the order of some ten micrometers.

According to one aspect of the invention, there is proposed a method for producing a resonant structure of a distributed-feedback semiconductor laser, the resonant structure comprising a multilayer stack of semi-conducting materials, the multilayer stack exhibiting at least two cavities defining a strip on the upper face of the stack, a diffraction grating being disposed on the strip.

The method comprises, in this order:
a first step of producing the strip comprising:
   a first sub-step of forming said cavities,
   a second sub-step of covering the upper face of the stack with a layer of dielectric material,
   a third sub-step of removing a part of the layer of dielectric material between said cavities to form an opening exposing a part of the semi-conducting material and serving as access to the electrical contact, the removal procedure being specific to the dielectric material,
a second step of producing the diffraction grating inside the opening on the strip comprising:
   a fourth sub-step of constructing metallic bands comprising a metallic layer on the upper face of the stack, the metallic bands serving as mask for the etching, the bands representing the negative of the pattern of the diffraction grating, and
   a fifth sub-step of specific dry etching of the semi-conducting material.

The production of the diffraction grating subsequent to the step of producing the strip makes it conceivable to prepare a multilayer stack stock comprising semi-conducting materials exhibiting a strip. In a last step, it is then possible to engrave a diffraction grating as a function of a desired precise wavelength.

By strip is meant the semi-conducting material band obtained on the surface of the stack after the formation of the cavities.

By waveguide is meant the strip on which the diffraction grating is disposed.

Advantageously, the removal of at least a part of the dielectric material is carried out by specific dry etching of the dielectric material.

Advantageously, the first sub-step of forming said cavities of the first step of producing said strip is carried out by anisotropic etching.

Advantageously, the layer of dielectric material comprises silica or silicon nitride or aluminum oxide or aluminum nitride and the dry etching is carried out with a plasma comprising CHF₃.

Advantageously, the specific dry etching of the semi-conducting material uses a plasma comprising methane.

Silica or silicon nitride are particularly appropriate materials: they serve as electrical insulator, they allow a strong contrast of index with the constituent semi-conducting materials of the stack thus allowing confinement of the optical mode in the multilayer stack of semi-conducting materials. Moreover, silica or silicon nitride are insensitive to reactive ion etching using a plasma comprising CH₄ allowing selective etching of the semi-conducting material during the engraving of the diffraction grating.

Advantageously, the fourth sub-step of constructing the metallic bands on the upper face of the stack comprises:
a first elementary step of covering the upper face of the multilayer stack with a provisional material,
a second elementary step of removing at least a part of the provisional material, the remaining provisional material reproducing the negative of the pattern of the diffraction grating,
a third elementary step of depositing a metallic layer on the whole of the upper face of the multilayer stack,
a fourth elementary step of removing the provisional material covered by the metallic layer.

Advantageously, the provisional material is poly(methylmethacrylate) or PMMA.

Advantageously, the metallic layer comprises two sub-layers: a first sub-layer comprising titanium serving as binding layer and a second sub-layer comprising platinum.

According to another aspect of the invention, there is proposed a distributed-feedback semiconductor laser resonant structure constructed according to the method described above in which the diffraction grating is perfectly centered on the dielectric layer and exhibits an axis of symmetry with direction parallel to the direction of the multilayer stack and passing through the middle of the opening.

Advantageously, the diffraction grating is etched on the semiconductor solely inside the opening of the layer of dielectric material.

Advantageously, the distance along a direction perpendicular to the direction of the stack between an end of the diffraction grating and the layer of dielectric material is less than 10 nm.

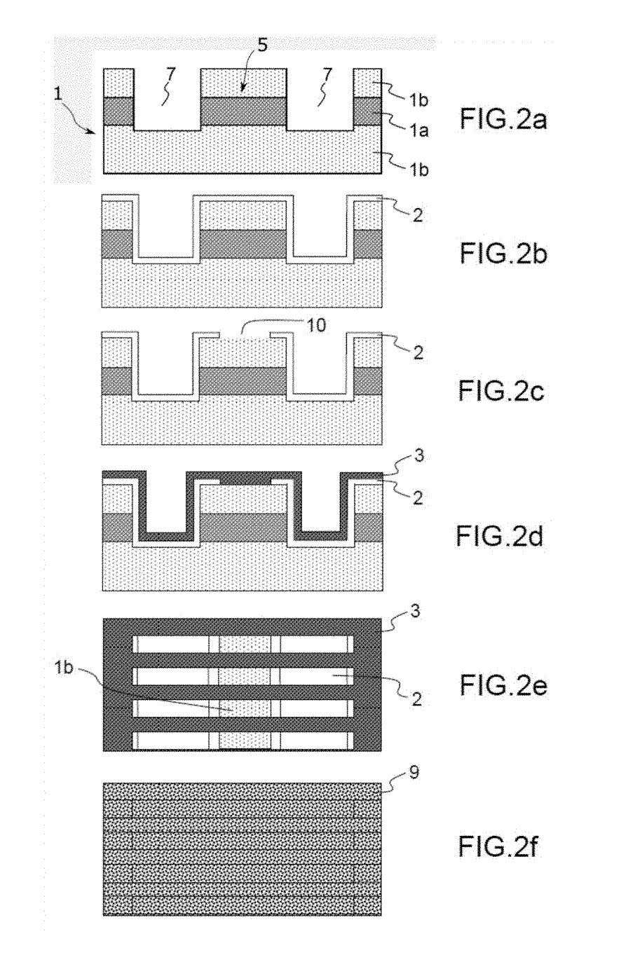

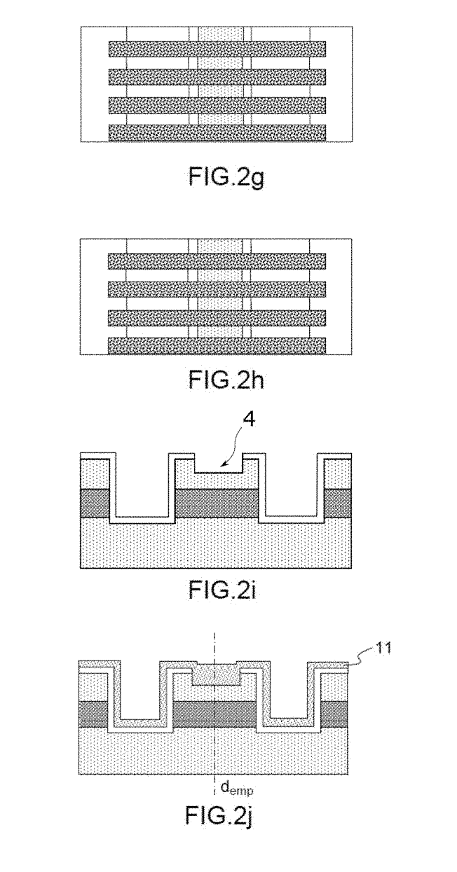

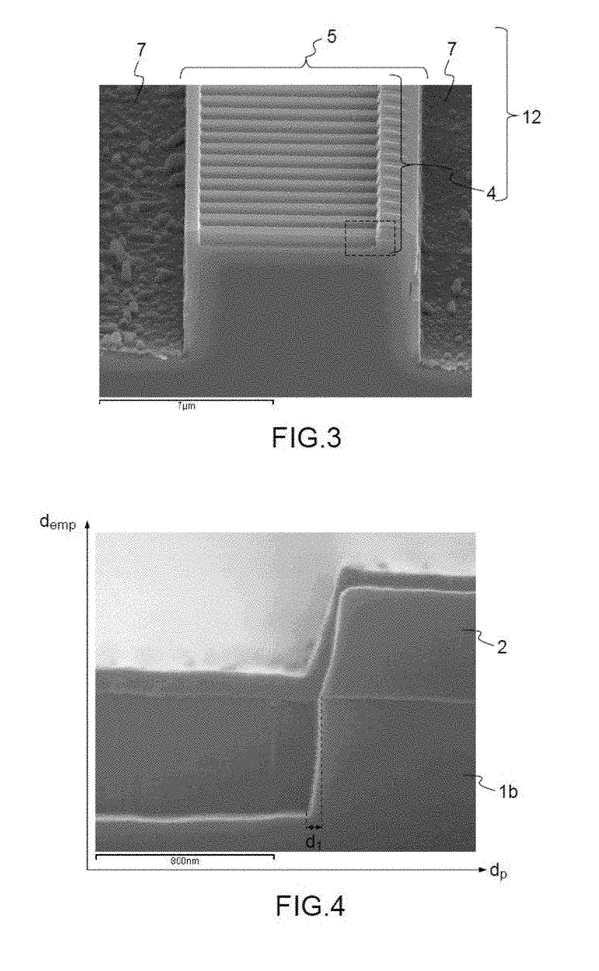

The invention will be better understood and other advantages will become apparent on reading the nonlimiting description which follows, and by virtue of the appended figures among which:
FIGS. 1a to 1m represent the resonant structure of a distributed-feedback semiconductor laser after various steps of a method of production according to the known art,
FIGS. 2a to 2j represent the resonant structure of a distributed-feedback semiconductor laser after various steps of the method of production according to one aspect of the invention,
the photo 3 represents an image obtained by a scanning electron microscope of a waveguide consisting of a strip on which is etched a diffraction grating according to one aspect of the invention,
the photo 4 represents a magnification of the zone framed in FIG. 3,
the photo 5 represents an image obtained by a scanning electron microscope of a longitudinal section along a plane passing through the diffraction grating, and
the photo 6 represents the final device after all the fabrication steps.

The method for producing a resonant structure of a distributed-feedback semiconductor laser according to one aspect of the invention is described in FIGS. 2a to 2j which represent the resonant structure after various steps of the method according to the invention.

The principle of the method relies on a step of producing the diffraction grating by dry etching subsequent to a step of constructing the waveguide.

FIG. 2a represents a stack 1 of a multitude of layers comprising semi-conducting materials 1a, 1b which is previously machined so as to create at least two cavities 7 and a strip 5 situated between the two cavities 7. In this step of the method, the strip 5 does not yet exhibit a diffraction grating.

Typically, the semi-conducting materials used comprise InP, AlInAs or GaInAs.

Advantageously, the machining is carried out by etching so as to form cavities 7. Preferentially, the cavities 7 are of rectangular shape. In one embodiment of the invention, the machining is carried out by means of anisotropic etching, so as to control the width of the cavities 7. The anisotropic etching may be a dry etching, for example a reactive ionic etching (RIE). Machining by anisotropic etching makes it possible to precisely control the width of the strip 5 with respect to a machining carried out by means of isotropic etching.

FIG. 2b represents the machined stack 1 after covering the upper surface of the stack 1 with a layer of dielectric material 2.

The electrical insulating material 2 advantageously comprises silica or Si₃N₄. Preferentially, the electrical insulating material 2 comprises silica allowing a strong contrast of optical index between the dielectric material 2 and the stack 1 comprising the semi-conducting materials 1a, 1b thus allowing confinement of the optical mode in the stack 1.

FIG. 2c represents the multilayer stack 1 after opening 10 of the silica layer 2, or, stated otherwise, after removing a part of the silica 2 situated on the strip 5.

The opening 10 of the silica layer 2 makes it possible to reveal the semi-conducting material 1b. The opening 10 of the silica layer 2 makes it possible to define the diffraction grating and the electrical contact.

FIG. 2d represents the stack 1 after totally covering the upper surface of the stack 1 with a layer of provisional material 3, the provisional material 3 serving as mask to define the pattern of the diffraction grating 4.

Advantageously, the provisional material 3 comprises poly(methylmethacrylate) or PMMA. An electron beam is applied to the surface of the PMMA, the beam reproducing the pattern of the diffraction grating 4 desired. After a step of development, or, stated otherwise, of immersion of the PMMA surface 3 in a solvent comprising acetone, all of the provisional material surface 3 that has been subjected to the electron beam is removed.

FIG. 2e represents a view from above of the stack 1.

The PMMA 3 remaining on the surface of the stack 1 represents a negative of the pattern of the diffraction grating 4, etched in a subsequent step, or, stated otherwise, the part without PMMA is hollowed out with respect to the part with PMMA, the hollowed out part without PMMA represents the pattern of the diffraction grating 4. The hollowed out part without PMMA evidences first zones exposing the semi-conducting material 1b and second zones exposing the electrical insulating material 2, in this instance, silica.

FIG. 2f represents the stack 1 after depositing a metallic layer 9. In this instance, the metallic layer 9 comprises two sub-layers disposed one on the other. The first sub-layer advantageously comprises titanium serving as binding layer and the second sub-layer advantageously comprises platinum so as to resist the plasma during the dry etching of the semi-conducting material.

FIG. 2g represents a view from above of the stack 1 after immersing the surface of the stack 1b in a bath comprising acetone so as to remove the PMMA mask 3. All of the PMMA 3 covered with the metallic layer 9 is thus removed, exposing the subjacent layer of dielectric material 2, in this instance, the silica, and the semi-conducting material 1b.

FIG. 2h represents the upper surface of the stack 1 after having carried out a dry etching of the semi-conducting material 1b. In this instance, the etching is a reactive ion etching or RIE procedure. The plasma used to carry out the etching advantageously comprises methane. The etching thus carried out is selective and etches only the semi-conducting material 1b without etching the silica 2 or the metallic layer 9.

FIG. 2i is a sectional view of the stack 1 along a plane parallel to the direction of the stack d_{Emp}.

FIG. 2j is a sectional view of the stack 1 along a plane parallel to the direction of the stack d_{Emp} and after depositing a metallic layer 11. In this instance, the metallic layer 11 comprises three superposed sub-layers. The first sub-layer advantageously comprises titanium serving as binding layer, the second sub-layer advantageously comprises platinum serving as diffusion barrier to the gold which constitutes the third sub-layer. The deposition of the metallic layer 11 makes it possible to fill the slots of the diffraction grating 4 with the aim of obtaining distributed feedback and of constructing an electrical contact.

This method for constructing a resonant structure making it possible to construct narrow waveguides in a reproducible manner.

Moreover, the resonant structure, constructed according to the invention, of a laser exhibits certain specific characteristics of the method of construction.

FIG. 2j evidences an axis of symmetry with direction parallel to the direction of the stack 1 and passing through the middle of the diffraction grating 4. Stated otherwise, the diffraction grating 4 is perfectly centered on the opening 10 of the dielectric layer 2. This characteristic was difficult to achieve with the method of the prior art such as described previously on account of the random contingencies related to the difficulty of alignment between the fabrication steps.

FIG. 3 is a photo recorded with the aid of a scanning electron microscope representing a view from above of a part of the resonant structure. FIG. 3 presents a waveguide 12 comprising the strip 5 on which a metallized diffraction grating 4 is etched. The width of the waveguide 12 is of the order of some ten micrometers. On either side of the waveguide 12, the cavities 7 are visible.

FIG. 4 is a magnification of the framed box of FIG. 3. This magnification makes it possible to evidence a characteristic of the structure obtained by the method of production.

Indeed, in this FIG. 4, the diffraction grating 4 is formed solely inside the opening 10, or, stated otherwise, the silica layer 2 does not cover a part of the diffraction grating 4 as was the case when constructing the resonant structure according to the prior art. A distance dl along a direction dₚ perpendicular to the direction of the stack d_{Emp} between an end of the diffraction grating 4 and the silica layer 2 is less than 10 nanometers.

The sub-step of covering the upper face of the stack 1 with a layer of dielectric material 2 and the sub-step of removing a part of the layer of dielectric material 2 between said cavities 7 to form an opening allow the construction of a gap between an end of the diffraction grating 4 and a cavity along the direction dₚ. The layer of dielectric material 2 thus formed protects the lateral walls of the strip 5 during a fifth sub-step of specific dry etching of the semi-conducting material. Without this protection, the lateral walls of the strip 5 could be affected by the dry etching of the fifth sub-step.

FIG. 5 is a photo recorded with the aid of a scanning electron microscope representing a sectional view along the periodic direction of the diffraction grating 4. This photo evidences the slots formed by the diffraction grating 4. The troughs comprise the etched semi-conducting material 1b and the surface of the crests comprises the metallic layer 9.

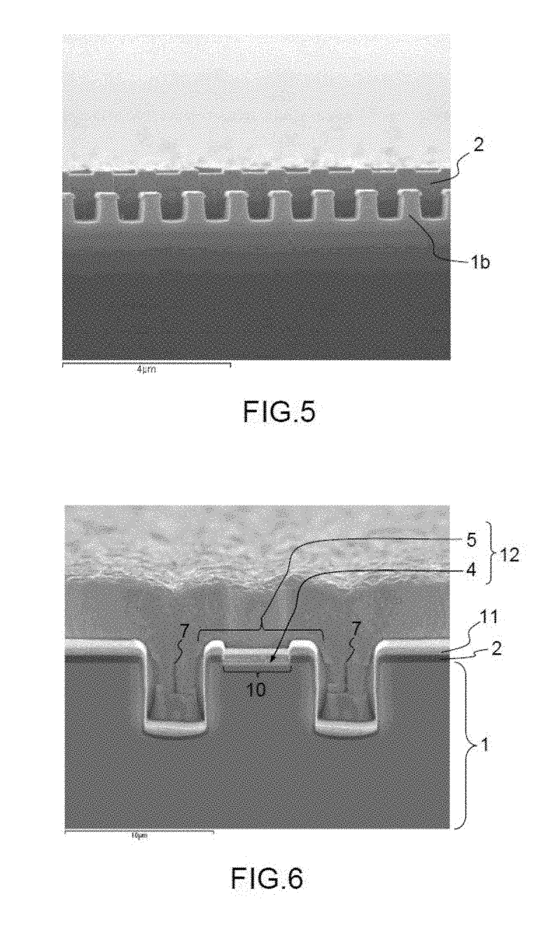

FIG. 6 represents the final device after all the construction steps. This zone evidences the stack 1 comprising semi-conducting materials 1a, 1b of AlInAs or GaInAs or InP type, the two cavities 7 making it possible to define the strip 5 on which an opening 10 is formed and inside which a diffraction grating 4 is etched, the whole forming the waveguide 12. A metallic layer 11 covers the whole of the structure. The waveguide 12 formed with the aid of the method described above has a width of about 8 micrometers.

1. A method for producing a resonant structure of a distributed-feedback semiconductor laser, the resonant structure comprising a multilayer stack of semi-conducting materials, the multilayer stack exhibiting at least two cavities defining a strip on the upper face of the stack, a diffraction grating being disposed on the strip, the method comprising, in this order:
a first step of producing the strip comprising:
a first sub-step of forming said cavities,
a second sub-step of covering the upper face of the stack with a layer of dielectric material,
a third sub-step of removing a part of the layer of dielectric material between said cavities to form an opening exposing a part of the semi-conducting material and serving as access to the electrical contact, the removal procedure being specific to the dielectric material,
a second step of producing the diffraction grating inside the opening on the strip comprising:
a fourth sub-step of constructing metallic bands comprising a metallic layer on the upper face of the stack, the metallic bands serving as mask for the etching, the bands representing the negative of the pattern of the diffraction grating, and
a fifth sub-step of specific dry etching of the semi-conducting material.

2. The method as claimed in claim 1, wherein the removal of at least a part of the dielectric material is carried out by specific dry etching of the dielectric material.

3. The method as claimed in claim 1, wherein the first sub-step of forming said cavities of the first step of producing said strip is carried out by an anisotropic etching.

4. The method as claimed in claim 1, wherein the layer of dielectric material comprises silica or silicon nitride or aluminum oxide or aluminum nitride.

5. The method as claimed in claim 1, wherein the dry etching is carried out with a plasma comprising CHF₃.

6. The method as claimed in claim 1, wherein the specific dry etching of the semi-conducting material uses a plasma comprising methane.

7. The method as claimed in claim 1, wherein the fourth sub-step of constructing the metallic bands on the upper face of the stack comprises:
a first elementary step of covering the upper face of the multilayer stack with a provisional material,
a second elementary step of removing a part of the provisional material, the remaining provisional material reproducing the negative of the pattern of the diffraction grating,
a third elementary step of depositing at least one metallic layer on the whole of the upper face of the multilayer stack,
a fourth elementary step of removing the provisional material covered by the metallic layer.

8. The method as claimed in claim 7, wherein the provisional material is poly(methylmethacrylate) or PMMA.

9. The method as claimed in claim 2, wherein the metallic layer comprises two sub-layers: a first sub-layer comprising titanium serving as binding layer and a second sub-layer comprising platinum.

10. A distributed-feedback semiconductor laser resonant structure constructed as claimed in claim 1, wherein the strip exhibits an axis of symmetry with direction parallel to the direction of the multilayer stack and passing through the middle of the opening.

11. The resonant structure as claimed in claim 10, wherein the diffraction grating is etched on the semiconductor solely inside the opening.

12. The resonant structure as claimed in claim 10, wherein the distance along a direction perpendicular to the direction of the stack between an end of the diffraction grating and the layer of dielectric material is less than 10 nm.
